(19) United States
(12) Patent Application Publication
(10) Pub. No.: US 2023/0178506 A1
(43) Pub. Date: Jun. 8, 2023

(54) POWER SEMICONDUCTOR APPARATUS AND METHOD OF MANUFACTURING THE SAME, AND POWER CONVERSION APPARATUS

(71) Applicant: Mitsubishi Electric Corporation, Tokyo (JP)

(72) Inventor: Tatsushi MORISADA, Chiyoda ku, Tokyo (JP)

(73) Assignee: Mitsubishi Electric Corporation, Tokyo (JP)

(21) Appl. No.: 17/917,270

(22) PCT Filed: Jun. 5, 2020
(86) PCT No.: PCT/JP2020/022335

§ 371 Date: Oct. 6, 2022

(51) Int. Cl. H01L 23/00; H01L 21/56; H01L 23/498; H01L 23/31

(52) U.S. Cl. CPC H01L 24/13; H01L 21/565; H01L 23/3121; H01L 23/49811; H01L 24/05; H01L 24/08; H01L 24/11; H01L 24/16; H01L 24/06; H01L 24/32; H01L 2224/0603; H01L 2224/1131; H01L 2224/1369; H01L 2224/1624; H01L 2224/05547; H01L 2224/05568; H01L 2224/05624; H01L 2224/05639; H01L 2224/05644; H01L 2224/05655; H01L 2224/06181; H01L 2224/08225; H01L 2224/11332; H01L 2224/11334; H01L 2224/11848; H01L 2224/11849; H01L 2224/13017; H01L 2224/13124; H01L 2224/13139; H01L 2224/13144; H01L 2224/13147; H01L 2224/13551; H01L 2224/13566; H01L 2224/13639; H01L 2224/13647; H01L 2224/13655; H01L 2224/32245

(57) ABSTRACT

A power semiconductor apparatus includes a conductive circuit pattern, a power semiconductor device, a sealing member, a conductive post, and a conductive post. A first conductive post is connected to the conductive circuit pattern. A second conductive post is connected to the power semiconductor device. The first conductive post includes a metal pin and a conductive bonding member. The conductive post includes a metal pin and a conductive bonding member.

### TECHNICAL FIELD

The present disclosure relates to a power semiconductor apparatus and a method of manufacturing the same, and a power conversion apparatus.

### BACKGROUND ART

Japanese Patent Laying-Open No. 2002-170906 (PTL 1) discloses a semiconductor device including a substrate, a semiconductor chip, a wire, an electrode pattern, a sealing resin, and a post. The semiconductor chip is fixed to the substrate. The electrode pattern is provided on the substrate. The wire is connected to the semiconductor chip and the electrode pattern. The sealing resin has a post hole. The post is formed in the post hole using high-speed Cu plating technology. One end of the post is connected to the electrode pattern, and the other end of the post protrudes from an outer surface of the sealing resin.

### CITATION LIST

### Patent Literature

PTL 1: Japanese Patent Laying-Open No. 2002-170906

### SUMMARY OF INVENTION

### Technical Problem

In a power semiconductor apparatus including a power semiconductor device, more heat is produced. When the power semiconductor apparatus is mounted on a substrate populated with an electronic component, it is necessary to protect the electronic component from heat produced in the power semiconductor device. Furthermore, due to a high voltage applied to the power semiconductor device and a conductive circuit pattern, a strong electric field is produced from the power semiconductor device and the conductive circuit pattern. It is also necessary to reduce adverse effects of electromagnetic noise caused by this strong electric field on the electronic component on the substrate and to prevent this strong electric field from causing dielectric breakdown in an insulating member (for example, a sealing member that seals the power semiconductor device) arranged between the power semiconductor device and the electronic component. It is therefore necessary to increase the height of the post and increase the distance between the power semiconductor device and the electronic component. In the high-speed Cu plating technology, however, the height of the post is unable to be increased in terms of post manufacturing time and post manufacturing cost.

The present disclosure is made in view of the problem above, and an object according to a first aspect of the present disclosure is to provide a power semiconductor apparatus in which a higher conductive post can be formed and having improved reliability, and a method of manufacturing the same. An object according to a second aspect of the present disclosure is to improve the reliability of a power conversion apparatus.

### Solution to Problem

A power semiconductor apparatus according to the present disclosure includes a conductive circuit pattern, a power semiconductor device, a sealing member, a first conductive post, and a second conductive post. The conductive circuit pattern includes a first main surface. The power semiconductor device is bonded on the first main surface of the conductive circuit pattern. The sealing member seals the first main surface of the conductive circuit pattern and the power semiconductor device. The first conductive post fills a first hole formed in the sealing member and is connected to the first main surface of the conductive circuit pattern. The second conductive post fills a second hole formed in the sealing member and is connected to the power semiconductor device. The first conductive post includes a first metal pin and a first conductive bonding member. The second conductive post includes a second metal pin and a second conductive bonding member. The first conductive bonding member fills between a first pin side surface of the first metal pin and a first side surface of the first hole and bonds the first metal pin to the conductive circuit pattern. The second conductive bonding member fills between a second pin side surface of the second metal pin and a second side surface of the second hole and bonds the second metal pin to the power semiconductor device.

A method of manufacturing a power semiconductor apparatus according to the present disclosure includes: bonding a power semiconductor device on a first main surface of a conductive circuit pattern; and providing a sealing member sealing the first main surface of the conductive circuit pattern and the power semiconductor device and having a first hole and a second hole. The method of manufacturing a power semiconductor apparatus according to the present disclosure includes: forming a first conductive post in the first hole of the sealing member; and forming a second conductive post in the second hole of the sealing member. Providing the sealing member includes placing the conductive circuit pattern having the power semiconductor device bonded thereon in a cavity of a mold having a first mold pin and a second mold pin, injecting a sealing resin material into the cavity of the mold, and curing the sealing resin material to obtain the sealing member. The first mold pin is arranged corresponding to the first hole of the sealing member. The second mold pin is arranged corresponding to the second hole of the sealing member. The first conductive post fills the first hole of the sealing member and is connected to the first main surface of the conductive circuit pattern. The second conductive post fills the second hole of the sealing member and is connected to the power semiconductor device. The first conductive post includes a first metal pin and a first conductive bonding member. The second conductive post includes a second metal pin and a second conductive bonding member. The first conductive bonding member fills between a first pin side surface of the first metal pin and a first side surface of the first hole and bonds the first metal pin to the conductive circuit pattern. The second conductive bonding member fills between a second pin side surface of the second metal pin and a second side surface of the second hole and bonds the second metal pin to the power semiconductor device.

A power conversion apparatus according to the present disclosure includes a main conversion circuit to convert input power and output the converted power, and a control circuit to output a control signal for controlling the main conversion circuit to the main conversion circuit. The main conversion circuit includes the semiconductor module according to the present disclosure.

### ADVANTAGEOUS EFFECTS OF INVENTION

In the power semiconductor apparatus according to the present disclosure, the first conductive post includes the first metal pin, and the second conductive post includes the second metal pin. This configuration can increase a first height of the first conductive post and a second height of the second conductive post. The first metal pin is bonded to the conductive circuit pattern and the sealing member by the first conductive bonding member. The second metal pin is bonded to the power semiconductor device and the sealing member by the second conductive bonding member. The reliability of the power semiconductor apparatus can be improved.

In the method of manufacturing a power semiconductor apparatus according to the present disclosure, the first conductive post includes the first metal pin, and the second conductive post includes the second metal pin. Thus, a higher first conductive post and a higher second conductive post can be formed. The first metal pin is bonded to the conductive circuit pattern and the sealing member by the first conductive bonding member. The second metal pin is bonded to the power semiconductor device and the sealing member by the second conductive bonding member. With the method of manufacturing a power semiconductor apparatus in the present embodiment, a power semiconductor apparatus with improved reliability can be obtained.

The power conversion apparatus according to the present disclosure includes the power semiconductor apparatus in the present disclosure and therefore has improved reliability.

### BRIEF DESCRIPTION OF DRAWINGS

FIG. 1 is a schematic cross-sectional view of a power semiconductor apparatus in a first embodiment.

FIG. 2 is a schematic cross-sectional view illustrating a step of a first example, a second example, and a third example of a method of manufacturing a power semiconductor apparatus in the first embodiment.

FIG. 3 is a schematic cross-sectional view illustrating a step subsequent to the step illustrated in FIG. 2 in the first example, the second example, and the third example of the method of manufacturing a power semiconductor apparatus in the first embodiment.

FIG. 4 is a schematic cross-sectional view illustrating a step subsequent to the step illustrated in FIG. 3 in the first example, the second example, and the third example of the method of manufacturing a power semiconductor apparatus in the first embodiment.

FIG. 5 is a schematic cross-sectional view illustrating a step subsequent to the step illustrated in FIG. 4 in the first example of the method of manufacturing a power semiconductor apparatus in the first embodiment.

FIG. 6 is a schematic cross-sectional view illustrating a step subsequent to the step illustrated in FIG. 5 in the first example of the method of manufacturing a power semiconductor apparatus in the first embodiment.

FIG. 7 is a schematic cross-sectional view illustrating a step subsequent to the step illustrated in FIG. 4 in the second example of the method of manufacturing a power semiconductor apparatus in the first embodiment.

FIG. 8 is a schematic cross-sectional view illustrating a step subsequent to the step illustrated in FIG. 4 in the third example of the method of manufacturing a power semiconductor apparatus in the first embodiment.

FIG. 9 is a schematic cross-sectional view of a power semiconductor module in the first embodiment.

FIG. 10 is a schematic cross-sectional view of a power semiconductor module in a modification to the first embodiment.

FIG. 11 is a schematic cross-sectional view of a power semiconductor apparatus in a second embodiment.

FIG. 12 is a schematic cross-sectional view of a power semiconductor apparatus in a modification to the second embodiment.

FIG. 13 is a schematic cross-sectional view of a power semiconductor apparatus in a third embodiment.

FIG. 14 is a schematic cross-sectional view of a power semiconductor apparatus in a modification to the third embodiment.

FIG. 15 is a schematic cross-sectional view of a power semiconductor apparatus in a fourth embodiment.

FIG. 16 is a schematic cross-sectional view of a power semiconductor apparatus in a modification to the fourth embodiment.

FIG. 17 is a block diagram illustrating a configuration of a power conversion system in a fifth embodiment.

### DESCRIPTION OF EMBODIMENTS

Embodiments of the present disclosure will be described below. The same configuration is denoted by the same reference numeral and a description thereof is not repeated.

### First Embodiment

Referring to FIG. 1, a power semiconductor apparatus 1 in a first embodiment will be described. Power semiconductor apparatus 1 includes a conductive circuit pattern 10, a power semiconductor device 15, a sealing member 20, a conductive post 30, a conductive post 33, and a conductive post 36.

Conductive circuit pattern 10 is formed of, for example, a metal material such as copper or aluminum. Conductive circuit pattern 10 includes a first main surface 10a. An insulating substrate (not illustrated) may be provided on a main surface 10b of conductive circuit pattern 10 on the side opposite to first main surface 10a. The insulating substrate may be formed of, for example, an inorganic material (ceramics material) such as alumina, aluminum nitride, or silicon nitride. The insulating substrate may be formed of, for example, a resin material such as epoxy resin, polyimide resin, or cyanate resin containing an inorganic filler (ceramics filler) such as alumina, aluminum nitride, or silicon nitride.

Power semiconductor device 15 is bonded on first main surface 10a of conductive circuit pattern 10, using a conductive bonding member (not illustrated). Power semiconductor device 15 is mainly formed of silicon or a wide bandgap semiconductor material such as silicon carbide, gallium nitride, or diamond. The conductive bonding member is, for example, solder such as lead-free solder or metal fine particle sintered body such as silver fine particle sintered body, copper fine particle sintered body, or nickel fine particle sintered body.

Power semiconductor device 15 is, for example, an insulated gate bipolar transistor (IGBT), a metal oxide semiconductor field-effect transistor (MOSFET), or a freewheeling diode (FWD). Power semiconductor device 15 includes, for example, a back electrode 16, a first front electrode 17, and a second front electrode 18. Back electrode 16 is provided on the back surface of power semiconductor device 15 opposed to first main surface 10a of conductive circuit pattern 10. Back electrode 16 is bonded to conductive circuit pattern 10 by a conductive bonding member (not illustrated). First front electrode 17 and second front electrode 18 are provided on the front surface of power semiconductor device 15 on the side opposite to the back surface of power semiconductor device 15. Power semiconductor device 15 is, for example, an IGBT. First front electrode 17 is, for example, a source electrode. Second front electrode 18 is, for example, a gate electrode. Back electrode 16 is, for example, a drain electrode.

Sealing member 20 seals first main surface 10a of conductive circuit pattern 10 and power semiconductor device 15. Main surface 10b of conductive circuit pattern 10 on the side opposite to first main surface 10a may be exposed from sealing member 20 or may be sealed by sealing member 20. Sealing member 20 is formed of, for example, a resin sealing material such as epoxy resin. Sealing member 20 includes a second main surface 20a away from first main surface 10a of conductive circuit pattern 10 in a direction normal to first main surface 10a of conductive circuit pattern 10.

Sealing member 20 has holes 22, 24, and 24. The longitudinal direction of hole 22 is, for example, the direction normal to first main surface 10a of conductive circuit pattern 10. Hole 22 extends to second main surface 20a of sealing member 20. In a planar view of second main surface 20a of sealing member 20, hole 22 exposes a part of first main surface 10a of conductive circuit pattern 10 from sealing member 20. The longitudinal direction of hole 23 is, for example, the direction normal to first main surface 10a of conductive circuit pattern 10. Hole 23 extends to second main surface 20a of sealing member 20. In a planar view of second main surface 20a of sealing member 20, hole 23 exposes a part of first front electrode 17 of power semiconductor device 15 from sealing member 20. The longitudinal direction of hole 24 is, for example, the direction normal to first main surface 10a of conductive circuit pattern 10. Hole 24 extends to second main surface 20a of sealing member 20. In a planar view of second main surface 20a of sealing member 20, hole 24 exposes a part of second front electrode 18 of power semiconductor device 15 from sealing member 20.

Conductive post 30 fills hole 22 of sealing member 20 and is connected to first main surface 10a of conductive circuit pattern 10. The longitudinal direction of conductive post 30 is, for example, the direction normal to first main surface 10a of conductive circuit pattern 10. An end portion of conductive post 30 distal from first main surface 10a of conductive circuit pattern 10 protrudes from second main surface 20a of sealing member 20. The height of conductive post 30 is, for example, 1.0 mm or more. The height of conductive post 30 is the length of conductive post 30 in the longitudinal direction of conductive post 30. The height of conductive post 30 may be, but not limited to, 100 mm or less, in terms of preventing bending and breaking of conductive post 30 and avoiding mechanical interference between conductive post 30 and other components.

Conductive post 30 includes a metal pin 31 and a conductive bonding member 32. The longitudinal direction of metal pin 31 is, for example, the direction normal to first main surface 10a of conductive circuit pattern 10. Metal pin 31 is formed of, for example, a metal material made of substantially a single metal element, such as copper, aluminum, gold, or silver. The metal material made of substantially a single metal element means a material composed of the single metal element and an inevitable impurity. The thermal conductivity of metal pin 31 may be higher than the thermal conductivity of conductive bonding member 32, and the electrical resistivity of metal pin 31 may be lower than the electrical resistivity of conductive bonding member 32.

Conductive bonding member 32 bonds metal pin 31 to conductive circuit pattern 10. Conductive bonding member 32 fills between a pin side surface of metal pin 31 and a side surface of hole 22. Conductive bonding member 35 bonds the pin side surface of metal pin 31 to the side surface of hole 22 of sealing member 20. Conductive bonding member 32 is formed of metal fine particle sintered body such as silver fine particle sintered body, copper fine particle sintered body, or nickel fine particle sintered body, solder, or a conductive adhesive containing resin and conductive particles dispersed in the resin.

Conductive post 33 fills hole 23 of sealing member 20 and is connected to power semiconductor device 15 (specifically, first front electrode 17). The longitudinal direction of conductive post 33 is, for example, the direction normal to first main surface 10a of conductive circuit pattern 10. An end portion of conductive post 33 distal from first main surface 10a of conductive circuit pattern 10 protrudes from second main surface 20a of sealing member 20. The height of conductive post 33 is, for example, 1.0 mm or more. The height of conductive post 33 is the length of conductive post 33 in the longitudinal direction of conductive post 33. The height of conductive post 33 may be, but not limited to, 100 mm or less, in terms of preventing bending and breaking of conductive post 33 and avoiding mechanical interference between conductive post 33 and other components.

Conductive post 33 includes a metal pin 34 and a conductive bonding member 35. The longitudinal direction of metal pin 34 is, for example, the direction normal to first main surface 10a of conductive circuit pattern 10. Metal pin 34 is formed of a metal material made of substantially a single metal element, such as copper, aluminum, gold, or silver. The metal material made of substantially a single metal element means a material composed of the single metal element and an inevitable impurity. The thermal conductivity of metal pin 34 may be higher than the thermal conductivity of conductive bonding member 35, and the electrical resistivity of metal pin 34 may be lower than the electrical resistivity of conductive bonding member 35.

Conductive bonding member 35 bonds metal pin 34 to power semiconductor device 15 (specifically, first front electrode 17). Conductive bonding member 35 fills between a pin side surface of metal pin 34 and a side surface of hole 23. Conductive bonding member 35 bonds the pin side surface of metal pin 34 to the side surface of hole 23 of sealing member 20. Conductive bonding member 35 is formed of metal fine particle sintered body such as silver fine particle sintered body, copper fine particle sintered body, or nickel fine particle sintered body, solder, or a conductive adhesive containing resin and conductive particles dispersed in the resin.

Conductive post 36 fills hole 24 of sealing member 20 and is connected to power semiconductor device 15 (specifically, second front electrode 18). The longitudinal direction of conductive post 36 is, for example, the direction normal to first main surface 10a of conductive circuit pattern 10. An end portion of conductive post 36 distal from first main surface 10a of conductive circuit pattern 10 protrudes from second main surface 20a of sealing member 20. The height of conductive post 36 is, for example, 1.0 mm or more. The height of conductive post 36 is the length of conductive post 36 in the longitudinal direction of conductive post 36. The height of conductive post 36 may be, but not limited to, 100 mm or less, in terms of preventing bending and breaking of conductive post 36 and avoiding mechanical interference between conductive post 36 and other components.

Conductive post 36 includes a metal pin 37 and a conductive bonding member 38. The longitudinal direction of metal pin 37 is, for example, the direction normal to first main surface 10a of conductive circuit pattern 10. Metal pin 37 is formed of a metal material made of substantially a single metal element, such as copper, aluminum, gold, or silver. The metal material made of substantially a single metal element means a material made of the single metal element and an inevitable impurity. The thermal conductivity of metal pin 37 may be higher than the thermal conductivity of conductive bonding member 38, and the electrical resistivity of metal pin 37 may be lower than the electrical resistivity of conductive bonding member 38.

Conductive bonding member 38 bonds metal pin 37 to power semiconductor device 15 (specifically, second front electrode 18). Conductive bonding member 38 fills between a pin side surface of metal pin 37 and a side surface of hole 24. Conductive bonding member 38 bonds the pin side surface of metal pin 37 to the side surface of hole 24 of sealing member 20. Conductive bonding member 38 is formed of metal fine particle sintered body such as silver fine particle sintered body, copper fine particle sintered body, or nickel fine particle sintered body, solder, or a conductive adhesive containing resin and conductive particles dispersed in the resin.

In operation of power semiconductor apparatus 1, first current flowing through metal pin 31 and second current flowing through metal pin 34 are each larger than third current flowing through metal pin 37. Therefore, the first sectional area of metal pin 31 and the second sectional area of metal pin 34 are each larger than the third sectional area of metal pin 37. The first sectional area of metal pin 31 is the area of metal pin 31 in a cross section perpendicular to the longitudinal direction of metal pin 31. The second sectional area of metal pin 34 is the area of metal pin 34 in a cross section perpendicular to the longitudinal direction of metal pin 34. The third sectional area of metal pin 37 is the area of metal pin 37 in a cross section perpendicular to the longitudinal direction of metal pin 37.

Referring to FIG. 1 to FIG. 6, a first example of a method of manufacturing power semiconductor apparatus 1 in the present embodiment will be described.

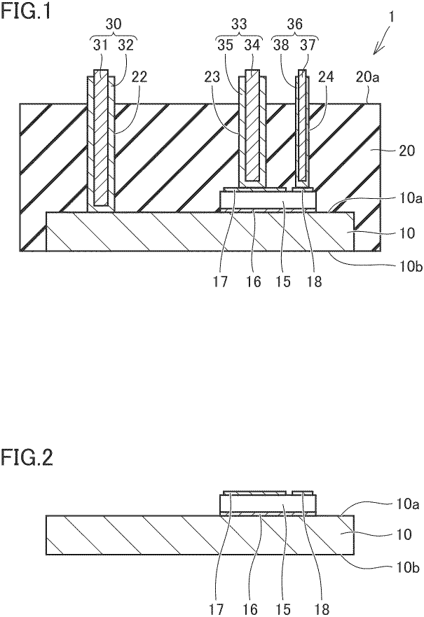

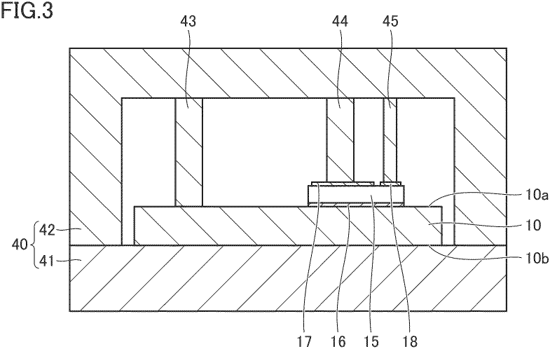

As illustrated in FIG. 2, the first example of the method of manufacturing power semiconductor apparatus 1 in the present embodiment includes bonding power semiconductor device 15 on first main surface 10a of conductive circuit pattern 10. Specifically, power semiconductor device 15 is bonded on first main surface 10a of conductive circuit pattern 10 using a conductive bonding member (not illustrated). The conductive bonding member is, for example, solder such as lead-free solder or metal fine particle sintered body such as silver fine particle sintered body, copper fine particle sintered body, or nickel fine particle sintered body.

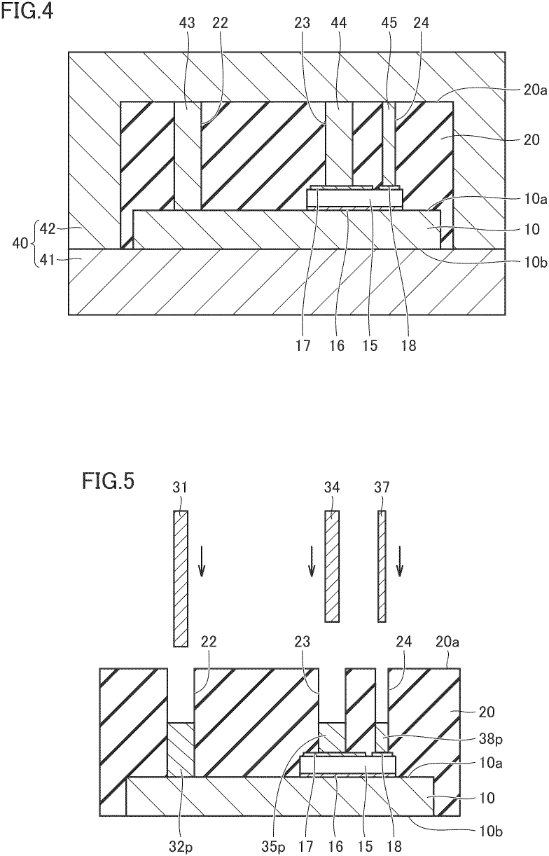

As illustrated in FIG. 3 and FIG. 4, the first example of the method of manufacturing power semiconductor apparatus 1 in the present embodiment includes providing sealing member 20. Sealing member 20 seals first main surface 10a of conductive circuit pattern 10 and power semiconductor device 15. Sealing member 20 has holes 22, 23, 24. Sealing member 20 is formed, for example, by transfer molding.

Specifically, as illustrated in FIG. 3, a mold 40 includes a fixed part 41 and a movable part 42. Conductive circuit pattern 10 having power semiconductor device 15 bonded thereon is placed on fixed part 41. Movable mold 42 is moved to close mold 40. Movable mold 42 has mold pins 43, 44, and 45. Mold pin 43 is arranged corresponding to hole 22 of sealing member 20. Mold pin 44 is arranged corresponding to hole 23 of sealing member 20. Mold pin 45 is arranged corresponding to hole 24 of sealing member 20. Conductive circuit pattern 10 having power semiconductor device 15 bonded thereon is placed in the cavity of mold 40 formed with movable part 42 and fixed part 41. As illustrated in FIG. 4, a resin sealing material is injected into the cavity of mold 40. The sealing resin material is cured to obtain sealing member 20. Power semiconductor device 15, conductive circuit pattern 10, and sealing member 20 are removed from mold 40.

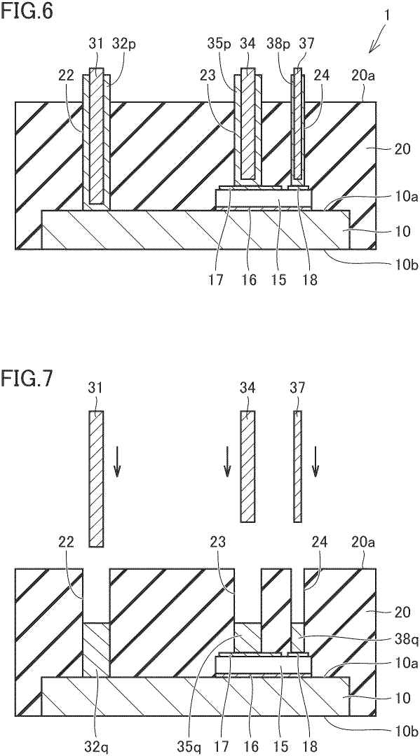

As illustrated in FIG. 5 and FIG. 6, the first example of the method of manufacturing power semiconductor apparatus 1 in the present embodiment includes forming conductive post 30 in hole 22 of sealing member 20, forming conductive post 33 in hole 23 of sealing member 20, and forming conductive post 36 in hole 24 of sealing member 20. Conductive post 30 fills hole 22 of sealing member 20 and is connected to first main surface 10a of conductive circuit pattern 10. Conductive post 33 fills hole 23 of sealing member 20 and is connected to power semiconductor device 15 (specifically, first front electrode 17). Conductive post 36 fills hole 24 of sealing member 20 and is connected to power semiconductor device 15 (specifically, second front electrode 18). Forming conductive post 30 in hole 22 of sealing member 20, forming conductive post 33 in hole 23 of sealing member 20, and forming conductive post 36 in hole 24 of sealing member 20 may be performed simultaneously.

Conductive post 30 includes metal pin 31 and conductive bonding member 32. Conductive bonding member 32 bonds metal pin 31 to conductive circuit pattern 10. Conductive bonding member 32 fills between a pin side surface of metal pin 31 and a side surface of hole 22. Conductive bonding member 32 bonds the pin side surface of metal pin 31 to the side surface of hole 22 of sealing member 20. Conductive post 33 includes metal pin 34 and conductive bonding member 35. Conductive bonding member 35 bonds metal pin 34 to power semiconductor device 15 (specifically, first front electrode 17). Conductive bonding member 35 fills between a pin side surface of metal pin 34 and a side surface of hole 23. Conductive bonding member 35 bonds the pin side surface of metal pin 34 to the side surface of hole 23 of sealing member 20. Conductive post 36 includes metal pin 37 and conductive bonding member 38. Conductive bonding member 38 bonds metal pin 37 to power semiconductor device 15 (specifically, second front electrode 18). Conductive bonding member 38 fills between a pin side surface of metal pin 37 and a side surface of hole 24. Conductive bonding member 38 bonds the pin side surface of metal pin 37 to the side surface of hole 24 of sealing member 20.

Specifically, conductive posts 30, 33, 36 are formed in holes 22, 23, 24 through the following steps. As illustrated in FIG. 5, a conductive bond precursor 32p in paste or powder form is provided in hole 22. A conductive bond precursor 35p in paste or powder form is provided in hole 23. A conductive bond precursor 38p in paste or powder form is provided in hole 24. Conductive bond precursors 32p, 35p, 38p are, for example, paste containing metallic fine particles or conductive particles, powder made of metallic fine particles or conductive particles, or solder powder.

As illustrated in FIG. 6, metal pin 31 is brought into contact with conductive bond precursor 32p. Conductive bond precursor 32p is arranged between metal pin 31 and conductive circuit pattern 10 and between the pin side surface of metal pin 31 and the side surface of hole 22. Metal pin 34 is brought into contact with conductive bond precursor 35p. Conductive bond precursor 35p is arranged between metal pin 34 and power semiconductor device 15 (specifically, first front electrode 17) and between the pin side surface of metal pin 34 and the side surface of hole 23. Metal pin 37 is brought into contact with conductive bond precursor 38p. Conductive bond precursor 38p is arranged between metal pin 37 and power semiconductor device 15 (specifically, second front electrode 18) and between the pin side surface of metal pin 37 and the side surface of hole 24.

When metal pins 31, 34, 37 are brought into contact with conductive bond precursors 32p, 35p, 38p, conductive bond precursors 32p, 35p, 38p are formed also on the portions of metal pins 31, 34, 37 on the side distal from conductive circuit pattern 10 with respect to second main surface 20a of sealing member 20. Specifically, a mask (not illustrated) is arranged on a front surface of second main surface 20a of sealing member 20. The mask has a first opening, a second opening, and a third opening. The first opening has the same diameter as that of hole 22 and is communicatively connected to hole 22. The second opening has the same diameter as that of hole 23 and is communicatively connected to hole 23. The third opening has the same diameter as that of hole 24 and is communicatively connected to hole 24. When metal pins 31, 34, 37 are brought into contact with conductive bond precursors 32p, 35p, 38p, conductive bond precursors 32p, 35p, 38p spilling out of holes 22, 23, 24 are formed on the portions of metal pins 31, 34, 37 on the side distal from conductive circuit pattern 10 with respect to second main surface 20a of sealing member 20. The mask is then removed.

Conductive bond precursor 32p is heated and cooled so that conductive bond precursor 32 changes into conductive bonding member 32. Conductive bond precursor 35p is heated and cooled so that conductive bond precursor 35p changes into conductive bonding member 35. Conductive bond precursor 38 is heated and cooled so that conductive bond precursor 38p changes into conductive bonding member 38. Conductive bond precursors 32p, 35p, 38p may be heated by heating all of the members that constitute power semiconductor apparatus 1 including conductive circuit pattern 10, power semiconductor device 15, and sealing member 20. When current is fed to metal pins 31, 34, 37, heat is produced in metal pins 31, 34, 37. This heat may be used to heat conductive bond precursors 32p, 35p, 38p.

Referring to FIG. 1 to FIG. 4 and FIG. 7, a second example of the method of manufacturing power semiconductor apparatus 1 in the present embodiment will be described. The second example of the method of manufacturing power semiconductor apparatus 1 in the present embodiment includes steps similar to those in the first example of the method of manufacturing power semiconductor apparatus 1 in the present embodiment (the steps illustrated in FIG. 2 to FIG. 4) but mainly differs in the following points.

Specifically, conductive posts 30, 33, 36 are formed in holes 22, 23, 24 through the following steps. As illustrated in FIG. 7, a conductive bond precursor 32q is provided in hole 22. A conductive bond precursor 35q is provided in hole 23. A conductive bond precursor 38q is provided in hole 24. Conductive bond precursors 32q, 35q, 38q are, for example, solder plate or solder rod.

Conductive bond precursors 32q, 35q, 38q are heated so that conductive bond precursors 32q, 35q, 38q are melted. Conductive bond precursors 32q, 35q, 38q may be heated by heating all of the members that constitute power semiconductor apparatus 1 including conductive circuit pattern 10, power semiconductor device 15, and sealing member 20.

Metal pin 31 is dipped in the molten conductive bond precursor 32q. Metal pin 34 is dipped in the molten conductive bond precursor 35q. Metal pin 37 is dipped in the molten conductive bond precursor 38q. The molten conductive bond precursor 32q is arranged between metal pin 31 and conductive circuit pattern 10 and between the pin side surface of metal pin 31 and the side surface of hole 22. The molten conductive bond precursor 35q is arranged between metal pin 34 and power semiconductor device 15 (specifically, first front electrode 17) and between the pin side surface of metal pin 34 and the side surface of hole 23. The molten conductive bond precursor 38q is arranged between metal pin 37 and power semiconductor device 15 (specifically, second front electrode 18) and between the pin side surface of metal pin 37 and the side surface of hole 24. The molten conductive bond precursors 32q, 35q, 38q are cooled to change into conductive bonding members 32, 35, 38.

When metal pins 31, 34, 37 are brought into contact with conductive bond precursors 32p, 35p, 38p, conductive bond precursors 32p, 35p, 38p are formed also on the portions of metal pins 31, 34, 37 on the side distal from conductive circuit pattern 10 with respect to second main surface 20a of sealing member 20. Specifically, a mask (not illustrated) is arranged on a front surface of second main surface 20a of sealing member 20. The mask has a first opening, a second opening, and a third opening. The first opening has the same diameter as that of hole 22 and is communicatively connected to hole 22. The second opening has the same diameter as that of hole 23 and is communicatively connected to hole 23. The third opening has the same diameter as that of hole 24 and is communicatively connected to hole 24. When metal pins 31, 34, 37 are brought into contact with the molten conductive bond precursors 32p, 35p, 38p, conductive bond precursors 32p, 35p, 38p spilling out of holes 22, 23, 24 are formed on the portions of metal pins 31, 34, 37 on the side distal from conductive circuit pattern 10 with respect to second main surface 20a of sealing member 20. The molten conductive bond precursors 32q, 35q, 38q are cooled to change into conductive bonding members 32, 35, 38. The mask is then removed.

Referring to FIG. 1 to FIG. 4 and FIG. 8, a third example of the method of manufacturing power semiconductor apparatus 1 in the present embodiment will be described. The third example of the method of manufacturing power semiconductor apparatus 1 in the present embodiment includes steps similar to those in the first example of the method of manufacturing power semiconductor apparatus 1 in the present embodiment (the steps illustrated in FIG. 2 to FIG. 4) but mainly differs in the following points.

Specifically, conductive posts 30, 33, 36 are formed in holes 22, 23, 24 through the following steps. As illustrated in FIG. 8, a conductive bond precursor 32r is applied on metal pin 31 by coating or vapor deposition. A conductive bond precursor 35r is applied on metal pin 34 by coating or vapor deposition. A conductive bond precursor 38r is applied on metal pin 37 by coating or vapor deposition. Conductive bond precursors 32r, 35r, 38r are, for example, a conductive paste containing resin and conductive particles (for example, silver particles, copper particles, nickel particles, or gold particles) dispersed in the resin, or a solder coating.

Metal pin 31 having conductive bond precursor 32r applied thereon is inserted into hole 22. Metal pin 34 having conductive bond precursor 35r applied thereon is inserted into hole 23. Metal pin 37 having conductive bond precursor 38r applied thereon is inserted into hole 24. Conductive bond precursor 32r is arranged between metal pin 31 and conductive circuit pattern 10 and between the pin side surface of metal pin 31 and the side surface of hole 22. Conductive bond precursor 35p is arranged between metal pin 34 and power semiconductor device 15 (specifically, first front electrode 17) and between the pin side surface of metal pin 34 and the side surface of hole 23. Conductive bond precursor 38r is arranged between metal pin 37 and power semiconductor device 15 (specifically, second front electrode 18) and between the pin side surface of metal pin 37 and the side surface of hole 24.

Conductive bond precursors 32r, 35r, 38r are heated and cooled so that conductive bond precursors 32rr, 35r, 38r change into conductive bonding members 32, 35, 38. Conductive bond precursors 32rr, 35r, 38r may be heated by heating all of the members that constitute power semiconductor apparatus 1 including conductive circuit pattern 10, power semiconductor device 15, and sealing member 20. When current is fed to metal pins 31, 34, 37, heat is produced in metal pins 31, 34, 37. This heat may be used to heat conductive bond precursors 32r, 35r, 38r.

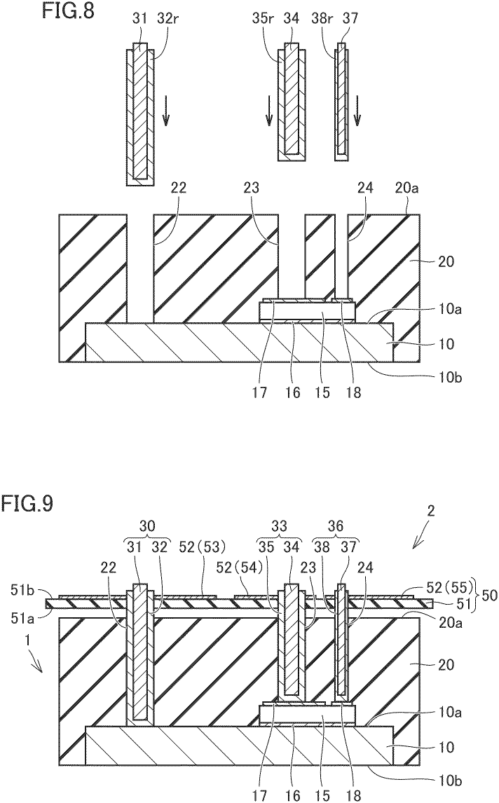

Referring to FIG. 9, a power semiconductor module 2 in the present embodiment will be described. Power semiconductor module 2 includes power semiconductor apparatus 1 and a printed circuit board 50.

Printed circuit board 50 includes an insulating substrate 51 and wiring 52. Insulating substrate 51 is, for example, a glass epoxy substrate or a glass composite substrate. The glass epoxy substrate is formed, for example, by curing glass cloth impregnated with epoxy resin by heat. The glass composite substrate is formed, for example, by curing glass nonwoven cloth impregnated with epoxy resin by heat. Insulating substrate 51 includes a third main surface 51a facing second main surface 20a of sealing member 20 and a fourth main surface 51b on the side opposite to third main surface 51a.

Wiring 52 is provided, for example, on fourth main surface 51b of insulating substrate 51. Wiring 52 may be provided on third main surface 51a of insulating substrate 51 or may be embedded in insulating substrate 51. Wiring 52 is, for example, a metal layer such as a copper foil. Wiring 52 includes a first wiring portion 53, a second wiring portion 54, and a third wiring portion 55. First wiring portion 53, second wiring portion 54, and third wiring portion 55 are spaced apart from each other. Printed circuit board 50 is populated with an electronic component (not illustrated) connected to wiring 52. The electronic component is, for example, a resistor, a capacitor, or a transformer.

Power semiconductor apparatus 1 is mounted on printed circuit board 50. Specifically, conductive post 30 is fixed to first wiring portion 53, for example, using conductive bonding member 32. Conductive post 33 is fixed to second wiring portion 54, for example, using conductive bonding member 35. Conductive post 36 is fixed to third wiring portion 55, for example, using conductive bonding member 38.

Referring to FIG. 10, a power semiconductor module 2a in a modification to the present embodiment will be described. Power semiconductor module 2a includes a power semiconductor apparatus 1a and a printed circuit board 50a in a modification to the present embodiment. In printed circuit board 50a, wiring 52 is provided on third main surface 51a of insulating substrate 51. In power semiconductor apparatus 1a, an end portion of conductive post 30 distal from first main surface 10a of conductive circuit pattern 10 is flush with second main surface 20a of sealing member 20. An end portion of conductive post 33 distal from first main surface 10a of conductive circuit pattern 10 is flush with second main surface 20a of sealing member 20. An end portion of conductive post 36 distal from first main surface 10a of conductive circuit pattern 10 is flush with second main surface 20a of sealing member 20. Power semiconductor apparatus 1a is surface-mounted on printed circuit board 50a.

The effects of power semiconductor apparatus 1, 1a in the present embodiment will be described.

Power semiconductor apparatus 1, 1a in the present embodiment includes conductive circuit pattern 10, power semiconductor device 15, sealing member 20, a first conductive post (conductive post 30), and a second conductive post (conductive post 33 or conductive post 36). Conductive circuit pattern 10 includes first main surface 10a. Power semiconductor device 15 is bonded on first main surface 10a of conductive circuit pattern 10. Sealing member 20 seals first main surface 10a of conductive circuit pattern 10 and power semiconductor device 15. The first conductive post fills a first hole (hole 22) formed in sealing member 20 and is connected to first main surface 10a of conductive circuit pattern 10. The second conductive post fills a second hole (hole 23 or hole 24) formed in sealing member 20 and is connected to power semiconductor device 15. The first conductive post includes a first metal pin (metal pin 31) and a first conductive bonding member (conductive bonding member 32). The second conductive post includes a second metal pin (metal pin 34 or metal pin 37) and a second conductive bonding member (conductive bonding member 35 or conductive bonding member 38). The first conductive bonding member fills between a first pin side surface of the first metal pin and a first side surface of the first hole and bonds the first metal pin to conductive circuit pattern 10. The second conductive bonding member fills between a second pin side surface of the second metal pin and a second side surface of the second hole and bonds the second metal pin to power semiconductor device 15.

The first conductive post (conductive post 30) includes the first metal pin (metal pin 31), and the second conductive post (conductive post 33 or conductive post 36) includes the second metal pin (metal pin 34 or metal pin 37). This configuration can increase a first height of the first conductive post and a second height of the second conductive post. The first metal pin is bonded firmly to conductive circuit pattern 10 and sealing member 20 by the first conductive bonding member (conductive bonding member 32). The second metal pin is bonded to power semiconductor device 15 and sealing member 20 by the second conductive bonding member (conductive bonding member 35 or conductive bonding member 38). The reliability of power semiconductor apparatus 1, 1a can be improved.

Compared with leading wires from conductive circuit pattern 10 and power semiconductor device 15, the first conductive post (conductive post 30) and the second conductive post (conductive post 33 or conductive post 36) enable size reduction of power semiconductor apparatus 1, 1a.

In power semiconductor apparatus 1, 1a in the present embodiment, the first metal pin (metal pin 31) and the second metal pin (metal pin 34 or metal pin 37) are formed of copper, aluminum, gold, or silver. The first metal pin and the second metal pin therefore have a high thermal conductivity and a low electrical resistivity. Heat produced in power semiconductor device 15 can be efficiently dissipated. The reliability of power semiconductor apparatus 1, 1a can be improved. More current can be fed to power semiconductor device 15. The electrical capacity of power semiconductor apparatus 1, 1a can be increased.

In power semiconductor apparatus 1, 1a in the present embodiment, the first conductive bonding member (conductive bonding member 32) and the second conductive bonding member (conductive bonding member 35 or conductive bonding member 38) are formed of solder or metal fine particle sintered body. The first metal pin (metal pin 31) is therefore bonded to conductive circuit pattern 10 and sealing member 20 by the first conductive bonding member. The second metal pin (conductive bonding member 32 or conductive bonding member 35) is bonded to power semiconductor device 15 and sealing member 20 by the second conductive bonding member. The reliability of power semiconductor apparatus 1, 1a can be improved.

In power semiconductor apparatus 1 in the present embodiment, sealing member 20 includes second main surface 20a away from first main surface 10a of conductive circuit pattern 10 in a direction normal to first main surface 10a of conductive circuit pattern 10. A first end portion of the first conductive post (conductive post 30) and a second end portion of the second conductive post (conductive post 33 or conductive post 36) distal from first main surface 10a of conductive circuit pattern 10 protrude from second main surface 20a of sealing member 20.

With this configuration, when power semiconductor apparatus 1 including power semiconductor device 15 is mounted on printed circuit board 50 populated with an electronic component, the distance between power semiconductor device 15 and the electronic component can be increased. The electronic component can be protected from heat produced in power semiconductor device 15. Power semiconductor apparatus 1 can be applied to more electrical products.

In power semiconductor apparatus 1a in the present embodiment, sealing member 20 includes second main surface 20a away from first main surface 10a in a direction normal to first main surface 10a of conductive circuit pattern 10. A first end portion of the first conductive post (conductive post 30) and a second end portion of the second conductive post (conductive post 33 or conductive post 36) distal from first main surface 10a of conductive circuit pattern 10 are flush with second main surface 20a of sealing member 20.

With this configuration, power semiconductor apparatus 1a including power semiconductor device 15 can be surface-mounted on printed circuit board 50a. Mounting of power semiconductor apparatus 1a on printed circuit board 50a becomes easy.

The method of manufacturing power semiconductor apparatus 1, 1a in the present embodiment includes: bonding power semiconductor device 15 on first main surface 10a of conductive circuit pattern 10; and providing sealing member 20 sealing first main surface 10a of conductive circuit pattern 10 and power semiconductor device 15 and having a first hole (hole 22) and a second hole (hole 23 or hole 24). The method of manufacturing power semiconductor apparatus 1, 1a in the present embodiment includes: forming a first conductive post (conductive post 30) in the first hole of sealing member 20; and forming a second conductive post (conductive post 33 or conductive post 36) in the second hole of sealing member 20. Providing sealing member 20 includes placing conductive circuit pattern 10 having power semiconductor device 15 bonded thereon in a cavity of mold 40 having a first mold pin (mold pin 43) and a second mold pin (mold pin 44 or mold pin 45), injecting a sealing resin material into the cavity of mold 40, and curing the sealing resin material to obtain sealing member 20. The first mold pin is arranged corresponding to the first hole of sealing member 20. The second mold pin is arranged corresponding to the second hole of sealing member 20.

The first conductive post (conductive post 30) fills the first hole (hole 22) of sealing member 20 and is connected to first main surface 10a of conductive circuit pattern 10. The second conductive post (conductive post 33 or conductive post 36) fills the second hole (hole 23 or hole 24) of sealing member 20 and is connected to power semiconductor device 15. The first conductive post includes a first metal pin (metal pin 31) and a first conductive bonding member (conductive bonding member 32). The second conductive post includes a second metal pin (metal pin 34 or metal pin 37) and a second conductive bonding member (conductive bonding member 35 or conductive bonding member 38). The first conductive bonding member fills between a first pin side surface of the first metal pin and a first side surface of the first hole and bonds the first metal pin to conductive circuit pattern 10. The second conductive bonding member fills between a second pin side surface of the second metal pin and a second side surface of the second hole and bonds the second metal pin to power semiconductor device 15.

The first conductive post (conductive post 30) includes the first metal pin (metal pin 31), and the second conductive post (conductive post 33 or conductive post 36) includes the second metal pin (metal pin 34 or metal pin 37). With the method of manufacturing power semiconductor apparatus 1, 1a in the present embodiment, a higher first conductive post and a higher second conductive post can be formed. The first metal pin is bonded to conductive circuit pattern 10 and sealing member 20 by the first conductive bonding member (conductive bonding member 32). The second metal pin is bonded to power semiconductor device 15 and sealing member 20 by the second conductive bonding member (conductive bonding member 35 or conductive bonding member 38). With the method of manufacturing power semiconductor apparatus 1, 1a in the present embodiment, power semiconductor apparatus 1, 1a with improved reliability can be obtained.

In the method of manufacturing power semiconductor apparatus 1, 1a in the present embodiment, after sealing member 20 having the first hole (hole 22) and the second hole (hole 23 or hole 24) is provided, the first conductive post (conductive post 30) and the second conductive post (conductive post 33 or conductive post 36) are formed. The sectional area (or diameter) of the first conductive post is predefined by the sectional area (or diameter) of the first hole. The first conductive post does not extend beyond the sectional area (or diameter) of the first hole in the in-plane direction parallel to first main surface 10a of conductive circuit pattern 10. The sectional area (or diameter) of the second conductive post is predefined by the sectional area (or diameter) of the second hole. The second conductive post does not extend beyond the sectional area (or diameter) of the second hole in the in-plane direction parallel to first main surface 10a of conductive circuit pattern 10. With this configuration, the distance between the first conductive post and the second conductive post can be reduced. With the method of manufacturing power semiconductor apparatus 1, 1a in the present embodiment, power semiconductor apparatus 1, 1a with a reduced size can be obtained.

Compared with leading wires from conductive circuit pattern 10 and power semiconductor device 15, the first conductive post (conductive post 30) and the second conductive post (conductive post 33 or conductive post 36) can reduce the size of power semiconductor apparatus 1, 1a. With the method of manufacturing power semiconductor apparatus 1, 1a in the present embodiment, power semiconductor apparatus 1, 1a with a reduced size can be obtained.

In the method of manufacturing power semiconductor apparatus 1, 1a in the present embodiment, forming the first conductive post (conductive post 30) in the first hole (hole 22) includes providing a first conductive bond precursor (conductive bond precursor 32p) in paste or powder form in the first hole, bringing the first metal pin (metal pin 31) into contact with the first conductive bond precursor to arrange the first conductive bond precursor between the first metal pin and conductive circuit pattern 10 and between the first pin side surface of the first metal pin and the first side surface of the first hole, and heating and cooling the first conductive bond precursor to change the first conductive bond precursor into the first conductive bonding member (conductive bonding member 32).

Forming the second conductive post (conductive post 33 or conductive post 36) in the second hole (hole 23 or hole 24) includes providing a second conductive bond precursor (conductive bond precursor 35p or conductive bond precursor 38p) in paste or powder form in the second hole, bringing the second metal pin (metal pin 34 or metal pin 37) into contact with the second conductive bond precursor to arrange the second conductive bond precursor between the second metal pin and power semiconductor device 15 and between the second pin side surface of the second metal pin and the second side surface of the second hole, and heating and cooling the second conductive bond precursor to change the second conductive bond precursor into the second conductive bonding member (conductive bonding member 35 or conductive bonding member 38).

The first conductive post (conductive post 30) includes the first metal pin (metal pin 31), and the second conductive post (conductive post 33 or conductive post 36) includes the second metal pin (metal pin 34 or metal pin 37). With the method of manufacturing power semiconductor apparatus 1, 1a in the present embodiment, a higher first conductive post and a higher second conductive post can be formed. The first metal pin is bonded to conductive circuit pattern 10 and sealing member 20 by the first conductive bonding member (conductive bonding member 32). The second metal pin is bonded to power semiconductor device 15 and sealing member 20 by the second conductive bonding member (conductive bonding member 35 or conductive bonding member 38). With the method of manufacturing power semiconductor apparatus 1, 1a in the present embodiment, the reliability of power semiconductor apparatus 1, 1a can be improved. With the method of manufacturing power semiconductor apparatus 1, 1a in the present embodiment, power semiconductor apparatus 1, 1a with a reduced size can be obtained.

In the method of manufacturing power semiconductor apparatus 1, 1a in the present embodiment, forming the first conductive post (conductive post 30) in the first hole (hole 22) includes providing a first conductive bond precursor (conductive bond precursor 32q) in the first hole, heating the first conductive bond precursor to melt the first conductive bond precursor, dipping the first metal pin (metal pin 31) in the molten first conductive bond precursor to arrange the molten first conductive bond precursor between the first metal pin and conductive circuit pattern 10 and between the first pin side surface of the first metal pin and the first side surface of the first hole, and cooling the first conductive bond precursor to change the first conductive bond precursor into the first conductive bonding member (conductive bonding member 32).

Forming the second conductive post (conductive post 33 or conductive post 36) in the second hole (hole 23 or hole 24) includes providing a second conductive bond precursor (conductive bond precursor 35q or conductive bond precursor 38q) in the second hole, heating the second conductive bond precursor to melt the second conductive bond precursor, dipping the second metal pin (metal pin 34 or metal pin 37) in the molten second conductive bond precursor to arrange the molten second conductive bond precursor between the second metal pin and power semiconductor device 15 and between the second pin side surface of the second metal pin and the second side surface of the second hole, and cooling the second conductive bond precursor to change the second conductive bond precursor into the second conductive bonding member (conductive bonding member 35 or conductive bonding member 38).

The first conductive post (conductive post 30) includes the first metal pin (metal pin 31), and the second conductive post (conductive post 33 or conductive post 36) includes the second metal pin (metal pin 34 or metal pin 37). With the method of manufacturing power semiconductor apparatus 1, 1a in the present embodiment, a higher first conductive post and a higher second conductive post can be formed. The first metal pin is bonded to conductive circuit pattern 10 and sealing member 20 by the first conductive bonding member (conductive bonding member 32). The second metal pin is bonded to power semiconductor device 15 and sealing member 20 by the second conductive bonding member (conductive bonding member 35 or conductive bonding member 38). With the method of manufacturing power semiconductor apparatus 1, 1a in the present embodiment, power semiconductor apparatus 1, 1a with improved reliability can be obtained. With the method of manufacturing power semiconductor apparatus 1, 1a in the present embodiment, power semiconductor apparatus 1, 1a with a reduced size can be obtained.

In the method of manufacturing power semiconductor apparatus 1, 1a in the present embodiment, forming the first conductive post (conductive post 30) in the first hole (hole 22) includes applying a first conductive bond precursor (conductive bond precursor 32r) on the first metal pin (metal pin 31), inserting the first metal pin having the first conductive bond precursor applied thereon into the first hole to arrange the first conductive bond precursor between the first metal pin and conductive circuit pattern 10 and between the first pin side surface of the first metal pin and the first side surface of the first hole, and heating and cooling the first conductive bond precursor to change the first conductive bond precursor into the first conductive bonding member (conductive bonding member 32).

Forming the second conductive post (conductive post 33 or conductive post 36) in the second hole (hole 23 or hole 24) includes applying a second conductive bond precursor (conductive bond precursor 35r or conductive bond precursor 38r) on the second metal pin (metal pin 34 or metal pin 37), inserting the second metal pin having the second conductive bond precursor applied thereon into the second hole to arrange the second conductive bond precursor between the second metal pin and power semiconductor device 15 and between the second pin side surface of the second metal pin and the second side surface of the second hole, and heating and cooling the second conductive bond precursor to change the second conductive bond precursor into the second conductive bonding member (conductive bonding member 35 or conductive bonding member 38).

The first conductive post (conductive post 30) includes the first metal pin (metal pin 31), and the second conductive post (conductive post 33 or conductive post 36) includes the second metal pin (metal pin 34 or metal pin 37). With the method of manufacturing power semiconductor apparatus 1, 1aa in the present embodiment, a higher first conductive post and a higher second conductive post can be formed. The first metal pin is bonded to conductive circuit pattern 10 and sealing member 20 by the first conductive bonding member (conductive bonding member 32). The second metal pin is bonded to power semiconductor device 15 and sealing member 20 by the second conductive bonding member (conductive bonding member 35 or conductive bonding member 38). With the method of manufacturing power semiconductor apparatus 1, 1a in the present embodiment, power semiconductor apparatus 1, 1a with improved reliability can be obtained. With the method of manufacturing power semiconductor apparatus 1, 1a in the present embodiment, power semiconductor apparatus 1, 1a with a reduced size can be obtained.

In the method of manufacturing power semiconductor apparatus 1, 1a in the present embodiment, the first conductive bond precursor (conductive bond precursor 32p, 32r) is heated using heat produced in the first metal pin (metal pin 31). The second conductive bond precursor (conductive bond precursor 35p, 35r or conductive bond precursor 38p, 38r) is heated using heat produced in the second metal pin (metal pin 34 or metal pin 37).

The first conductive bond precursor (conductive bond precursor 32p, 32r) and the second conductive bond precursor (conductive bond precursor 35p, 35r or conductive bond precursor 38p, 38r) therefore can be heated intensively. Thermal damage to a member forming power semiconductor apparatus 1, 1a, such as power semiconductor device 15 or sealing member 20, can be reduced. With the method of manufacturing power semiconductor apparatus 1, 1a in the present embodiment, power semiconductor apparatus 1, 1a with improved reliability can be obtained.

### Second Embodiment

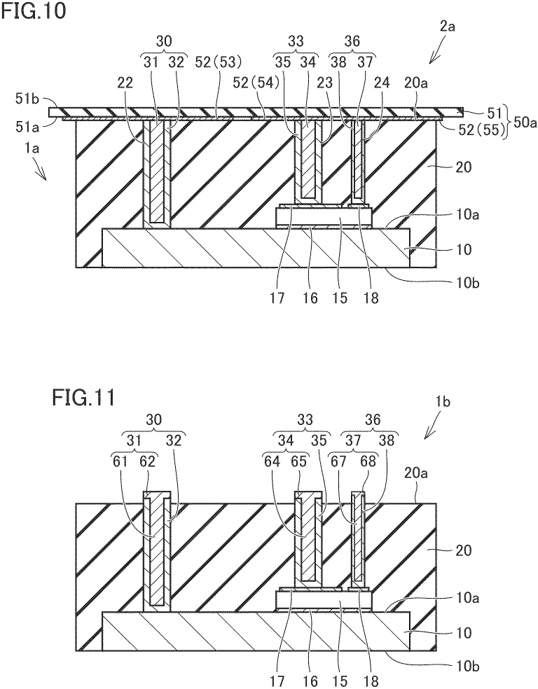

Referring to FIG. 11, a power semiconductor apparatus 1b in a second embodiment will be described. Power semiconductor apparatus 1b in the present embodiment has a configuration similar to power semiconductor apparatus 1 in the first embodiment, and a method of manufacturing power semiconductor apparatus 1bb in the present embodiment includes steps similar to those in the method of manufacturing power semiconductor apparatus 1 in the first embodiment but mainly differs in the following points.

In power semiconductor apparatus 1b and the method of manufacturing the same in the present embodiment, the cross section of metal pin 31 along the longitudinal direction of metal pin 31 has a T shape. Metal pin 31 includes a body 61 and a head 62 provided at a distal end of body 61 with respect to first main surface 10a of conductive circuit pattern 10. The sectional area of head 62 is larger than the sectional area of body 61. The sectional area of body 61 is the area of body 61 in a cross section perpendicular to the longitudinal direction of metal pin 31. The sectional area of head 62 is the area of head 62 in a cross section perpendicular to the longitudinal direction of metal pin 31.

The cross section of metal pin 34 along the longitudinal direction of metal pin 34 has a T shape. Metal pin 34 includes a body 64 and a head 65 provided at a distal end of body 64 with respect to first main surface 10a of conductive circuit pattern 10. The sectional area of head 65 is larger than the sectional area of body 64. The sectional area of body 64 is the area of body 64 in a cross section perpendicular to the longitudinal direction of metal pin 34. The sectional area of head 65 is the area of head 65 in a cross section perpendicular to the longitudinal direction of metal pin 34.

The cross section of metal pin 37 along the longitudinal direction of metal pin 37 has a T shape. Metal pin 37 includes a body 67 and a head 68 provided at a distal end of body 67 with respect to first main surface 10a of conductive circuit pattern 10. The sectional area of head 68 is larger than the sectional area of body 67. The sectional area of body 67 is the area of body 67 in a cross section perpendicular to the longitudinal direction of metal pin 37. The sectional area of head 68 is the area of head 68 in a cross section perpendicular to the longitudinal direction of metal pin 37.

As illustrated in FIG. 12, in a power semiconductor apparatus 1c and a method of manufacturing the same in a modification to the present embodiment, the cross section of metal pin 31 along the longitudinal direction of metal pin 31 has an I shape. Metal pin 31 includes a body 61, a head 62 provided at a distal end of body 61 with respect to first main surface 10a of conductive circuit pattern 10, and a leg 63 provided at a proximal end of body 61 with respect to first main surface 10a of conductive circuit pattern 10. The sectional area of head 62 is larger than the sectional area of body 61. The sectional area of leg 63 is larger than the sectional area of body 61. The sectional area of leg 63 is the area of leg 63 in a cross section perpendicular to the longitudinal direction of metal pin 31.

The cross section of metal pin 34 along the longitudinal direction of metal pin 34 has an I shape. Metal pin 34 includes a body 64, a head 65 provided at a distal end of body 64 with respect to first main surface 10a of conductive circuit pattern 10, and a leg 66 provided at a proximal end of body 64 with respect to first main surface 10a of conductive circuit pattern 10. The sectional area of head 65 is larger than the sectional area of body 64. The sectional area of leg 66 is larger than the sectional area of body 64. The sectional area of leg 66 is the area of leg 66 in a cross section perpendicular to the longitudinal direction of metal pin 34.

The cross section of metal pin 37 along the longitudinal direction of metal pin 37 has an I shape. Metal pin 37 includes a body 67, a head 68 provided at a distal end of body 67 with respect to first main surface 10a of conductive circuit pattern 10, and a leg 69 provided at a proximal end of body 67 with respect to first main surface 10a of conductive circuit pattern 10. The sectional area of head 68 is larger than the sectional area of body 67. The sectional area of leg 69 is larger than the sectional area of body 67. The sectional area of leg 69 is the area of leg 69 in a cross section perpendicular to the longitudinal direction of metal pin 37.

Power semiconductor apparatus 1b, 1c and the method of manufacturing the same in the present embodiment achieve the following effects, in addition to the effects achieved by power semiconductor apparatus 1 and the method of manufacturing the same in the first embodiment.

In power semiconductor apparatus 1b, 1c and the method of manufacturing the same in the present embodiment, a first cross section of the first metal pin (metal pin 31) along a first longitudinal direction of the first metal pin and a second cross section of the second metal pin (metal pin 34 or metal pin 37) along a second longitudinal direction of the second metal pin have a T shape or an I shape.

With this configuration, when the first metal pin (metal pin 31) is inserted into the first hole (hole 22), the first metal pin crushes voids included in the first conductive bond precursor (conductive bond precursor 32p, 32q, see FIG. 5 to FIG. 7) provided in the first hole. The first metal pin is bonded to conductive circuit pattern 10 and sealing member 20 more firmly. When the second metal pin (metal pin 34 or metal pin 37) is inserted into the second hole (hole 23 or hole 24), the second metal pin crushes voids included in the second conductive bond precursor (conductive bond precursor 35p, 35q or conductive bond precursor 38p, 38q, see FIG. 5 to FIG. 7) provided in the second hole. The second metal pin is bonded to power semiconductor device 15 and sealing member 20 more firmly. The reliability of power semiconductor apparatus 1b, 1c can be improved.

### Third Embodiment

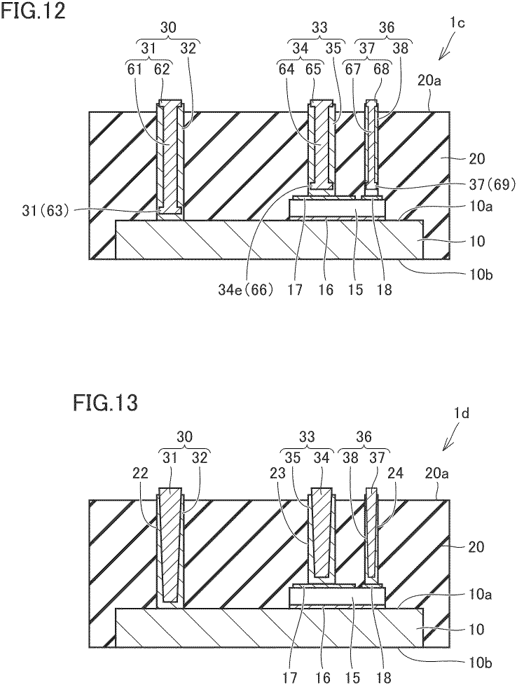

Referring to FIG. 13, a power semiconductor apparatus 1d in a third embodiment will be described. Power semiconductor apparatus 1d in the present embodiment has a configuration similar to power semiconductor apparatus 1 in the first embodiment, and a method of manufacturing power semiconductor apparatus 1d in the present embodiment includes steps similar to those in the method of manufacturing power semiconductor apparatus 1 in the first embodiment but mainly differs in the following points.

In power semiconductor apparatus 1d and the method of manufacturing the same in the present embodiment, the cross section of metal pin 31 along the longitudinal direction of metal pin 31 has a tapered shape becoming narrower toward first main surface 10a of conductive circuit pattern 10. The sectional area of one end of metal pin 31 distal from first main surface 10a of conductive circuit pattern 10 is larger than the sectional area of the other end of metal pin 31 proximal to first main surface 10a of conductive circuit pattern 10.

The cross section of metal pin 34 along the longitudinal direction of metal pin 34 has a tapered shape becoming narrower toward first main surface 10a of conductive circuit pattern 10. The sectional area of one end of metal pin 34 distal from first main surface 10a (or power semiconductor device 15) of conductive circuit pattern 10 is larger than the sectional area of the other end of metal pin 34 proximal to first main surface 10aa (or power semiconductor device 15) of conductive circuit pattern 10.

The cross section of metal pin 37 along the longitudinal direction of metal pin 37 has a tapered shape becoming narrower toward first main surface 10a of conductive circuit pattern 10. The sectional area of one end of metal pin 37 distal from first main surface 10a (or power semiconductor device 15) of conductive circuit pattern 10 is larger than the sectional area of the other end of metal pin 37 proximal to first main surface 10a (or power semiconductor device 15) of conductive circuit pattern 10.

As illustrated in FIG. 14, in a power semiconductor apparatus 1e and a method of manufacturing the same in a modification to the present embodiment, the cross section of metal pin 31 along the longitudinal direction of metal pin 31 has a serrated shape becoming narrower toward first main surface 10a of conductive circuit pattern 10. The cross section of metal pin 34 along the longitudinal direction of metal pin 34 has a serrated shape becoming narrower toward first main surface 10a of conductive circuit pattern 10. The cross section of metal pin 37 along the longitudinal direction of metal pin 37 has a serrated shape becoming narrower toward first main surface 10a of conductive circuit pattern 10.

Power semiconductor apparatus 1d, le and the method of manufacturing the same in the present embodiment achieve the following effects, in addition to the effects achieved by power semiconductor apparatus 1 and the method of manufacturing the same in the first embodiment.

In power semiconductor apparatus 1d, le in the present embodiment, a first cross section of the first metal pin (metal pin 31) along a first longitudinal direction of the first metal pin and a second cross section of the second metal pin (metal pin 34 or metal pin 37) along a second longitudinal direction of the second metal pin have a tapered shape or a serrated shape becoming narrower toward first main surface 10a of conductive circuit pattern 10.

With this configuration, when the first metal pin (metal pin 31) is inserted into the first hole (hole 22), the first metal pin crushes voids included in the conductive bond precursor (conductive bond precursor 32p, 32q, see FIG. 5 to FIG. 7) provided in the first hole. The first metal pin is bonded to conductive circuit pattern 10 and sealing member 20 more firmly. When the second metal pin (metal pin 34 or metal pin 37) is inserted into the second hole (hole 23 or hole 24), the second metal pin crushes voids included in the conductive bond precursor (conductive bond precursor 350, 35q or conductive bond precursor 38p, 38q, see FIG. 5 to FIG. 7) provided in the second hole. The second metal pin is bonded to power semiconductor device 15 and sealing member 20 more firmly. The reliability of power semiconductor apparatus 1d, 1e can be improved.

When the first metal pin (metal pin 31) is inserted into the first hole (hole 22), the center axis in the first longitudinal direction of the first metal pin is aligned with the center axis in the second longitudinal direction of the first hole by the side surface of the first metal pin even if the center axis in the first longitudinal direction of the first metal pin is misaligned with the center axis in the second longitudinal direction of the first hole. The first conductive bonding member (conductive bonding member 32) is formed uniformly around the first metal pin. When the second metal pin (metal pin 34 or metal pin 37) is inserted into the second hole (hole 23 or hole 24), the center axis in the third longitudinal direction of the second metal pin is aligned with the center axis in the fourth longitudinal direction of the second hole by the side surface of the second metal pin even if the center axis in the third longitudinal direction of the second metal pin is misaligned with the center axis in the fourth longitudinal direction of the second hole. The second conductive bonding member (conductive bonding member 35 or conductive bonding member 38) is formed uniformly around the second metal pin. With this configuration, even when stress is applied to the first conductive post (conductive post 30) and the second conductive post (conductive post 33 or conductive post 36) due to change in ambient temperature, the stress can be prevented from being strongly applied locally to a part of the first conductive post (conductive post 30) and the second conductive post (conductive post 33 or conductive post 36). The reliability of the first conductive post (conductive post 30) and the second conductive post (conductive post 33 or conductive post 36) can be improved, and the reliability of power semiconductor apparatus 1d, 1e can be improved. The productivity of power semiconductor apparatus 1d, 1e can be improved.

### Fourth Embodiment

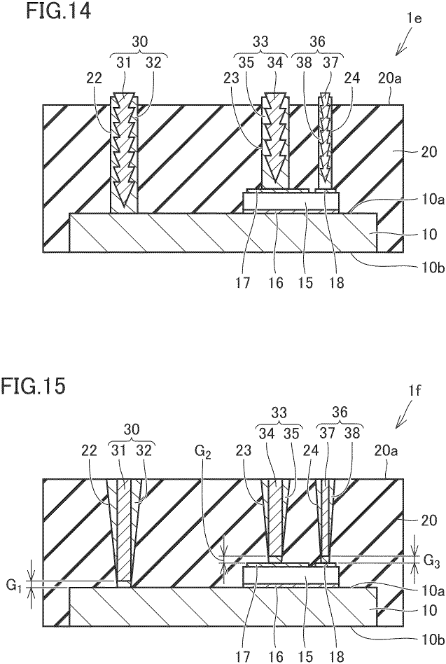

Referring to FIG. 15, a power semiconductor apparatus If in a fourth embodiment will be described. Power semiconductor apparatus If in the present embodiment has a configuration similar to power semiconductor apparatus 1 in the first embodiment, and a method of manufacturing power semiconductor apparatus If in the present embodiment includes steps similar to those in the method of manufacturing power semiconductor apparatus 1 in the first embodiment but mainly differs in the following points.

In power semiconductor apparatus If and the method of manufacturing the same in the present embodiment, the diameter of a proximal end of hole 22 with respect to first main surface 10a of conductive circuit pattern 10 is smaller than the diameter of a distal end of hole 22 with respect to first main surface 10a of conductive circuit pattern 10. Hole 22 positions metal pin 31 in the direction normal to first main surface 10a of conductive circuit pattern 10. Specifically, hole 22 has a tapered shape becoming narrower toward first main surface 10a of conductive circuit pattern 10.

The proximal end of metal pin 31 with respect to first main surface 10a of conductive circuit pattern 10 abuts on the side surface of hole 22 and thereby metal pin 31 is positioned in the direction normal to first main surface 10a of conductive circuit pattern 10.

The diameter of a proximal end of hole 23 with respect to first main surface 10a of conductive circuit pattern 10 is smaller than the diameter of a distal end of hole 23 with respect to first main surface 10a of conductive circuit pattern 10. Hole 23 positions metal pin 34 in the direction normal to first main surface 10a of conductive circuit pattern 10. Specifically, hole 23 has a tapered shape becoming narrower toward first main surface 10a of conductive circuit pattern 10. The proximal end of metal pin 34 with respect to first main surface 10a of conductive circuit pattern 10 abuts on the side surface of hole 23 and thereby metal pin 34 is positioned in the direction normal to first main surface 10a of conductive circuit pattern 10.

The diameter of a proximal end of hole 24 with respect to first main surface 10a of conductive circuit pattern 10 is smaller than the diameter of a distal end of hole 24 with respect to first main surface 10a of conductive circuit pattern 10. Hole 24 positions metal pin 37 in the direction normal to first main surface 10a of conductive circuit pattern 10. Specifically, hole 24 has a tapered shape becoming narrower toward first main surface 10a of conductive circuit pattern 10. The proximal end of metal pin 37 with respect to first main surface 10a of conductive circuit pattern 10 abuts on the side surface of hole 24 and thereby metal pin 37 is positioned in the direction normal to first main surface 10a of conductive circuit pattern 10.

As illustrated in FIG. 16, in a power semiconductor apparatus 1g and a method of manufacturing the same in a modification to the present embodiment, metal pin 31 includes a body 61 and a head 62 provided at a distal end of body 61 with respect to first main surface 10a of conductive circuit pattern 10. The diameter of head 62 is larger than the diameter of body 61. Hole 22 has a small diameter portion 71 and a large diameter portion 72 communicatively connected to small diameter portion 71. Large diameter portion 72 has a larger diameter than small diameter portion 71 and is more distal from first main surface 10a of conductive circuit pattern 10 than small diameter portion 71.

The diameter of body 61 of metal pin 31 is smaller than the diameter of small diameter portion 71 of hole 22 and smaller than the diameter of large diameter portion 72 of hole 22. The diameter of head 62 of metal pin 31 is larger than the diameter of small diameter portion 71 of hole 22 and smaller than the diameter of large diameter portion 72 of hole 22. Small diameter portion 71 of hole 22 accommodates body 61 of metal pin 31. Large diameter portion 72 of hole 22 accommodates head 62 of metal pin 31. Head 62 of metal pin 31 abuts on the bottom surface of large diameter portion 72 of hole 22 and thereby metal pin 31 is positioned in the direction normal to first main surface 10a of conductive circuit pattern 10.

Metal pin 34 includes a body 64 and a head 65 provided at a distal end of body 64 with respect to first main surface 10a of conductive circuit pattern 10. The diameter of head 65 is larger than the diameter of body 64. Hole 23 has a small diameter portion 74 and a large diameter portion 75 communicatively connected to small diameter portion 74. Large diameter portion 75 has a larger diameter than small diameter portion 74 and is more distal from first main surface 10a of conductive circuit pattern 10 than small diameter portion 74.

The diameter of body 64 of metal pin 34 is smaller than the diameter of small diameter portion 74 of hole 23 and smaller than the diameter of large diameter portion 75 of hole 23. The diameter of head 65 of metal pin 34 is larger than the diameter of small diameter portion 74 of hole 23 and smaller than the diameter of large diameter portion 75 of hole 23. Small diameter portion 74 of hole 23 accommodates body 64 of metal pin 34. Large diameter portion 75 of hole 23 accommodates head 65 of metal pin 34. Head 65 of metal pin 34 abuts on the bottom surface of large diameter portion 75 of hole 23 and thereby metal pin 34 is positioned in the direction normal to first main surface 10a of conductive circuit pattern 10.

Metal pin 37 includes a body 67 and a head 68 provided at a distal end of body 67 with respect to first main surface 10a of conductive circuit pattern 10. The diameter of head 68 is larger than the diameter of body 67. Hole 24 has a small diameter portion 77 and a large diameter portion 78 communicatively connected to small diameter portion 77. Large diameter portion 78 has a larger diameter than small diameter portion 77 and is more distal from first main surface 10aa of conductive circuit pattern 10 than small diameter portion 77.

The diameter of body 67 of metal pin 37 is smaller than the diameter of small diameter portion 77 of hole 24 and smaller than the diameter of large diameter portion 78 of hole 24. The diameter of head 68 of metal pin 37 is larger than the diameter of small diameter portion 77 of hole 24 and smaller than the diameter of large diameter portion 78 of hole 24. Small diameter portion 77 of hole 24 accommodates body 67 of metal pin 37. Large diameter portion 78 of hole 24 accommodates head 68 of metal pin 37. Head 68 of metal pin 37 abuts on the bottom surface of large diameter portion 78 of hole 24 and thereby metal pin 37 is positioned in the direction normal to first main surface 10a of conductive circuit pattern 10.

Power semiconductor apparatus 1f, 1g and the method of manufacturing the same in the present embodiment achieve the following effects, in addition to the effects achieved by power semiconductor apparatus 1 and the method of manufacturing the same in the first embodiment.

In power semiconductor apparatus 1f, 1g and the method of manufacturing the same in the present embodiment, a first diameter of a first proximal end of the first hole (hole 22) with respect to first main surface 10a of conductive circuit pattern 10 is smaller than a second diameter of a first distal end of the first hole with respect to first main surface 10a of conductive circuit pattern 10. The first hole positions the first metal pin (metal pin 31) in the direction normal to first main surface 10a of conductive circuit pattern 10. A third diameter of a second proximal end of the second hole (hole 23 or hole 24) with respect to first main surface 10a of conductive circuit pattern 10 is smaller than a fourth diameter of a second distal end of the second hole with respect to first main surface 10a of conductive circuit pattern 10. The second hole positions the second metal pin (metal pin 34 or metal pin 37) in the direction normal to first main surface 10a of conductive circuit pattern 10.

With this configuration, a first distance (distance G₁) between conductive circuit pattern 10 and the first metal pin (metal pin 31) and a second distance (distance G₂ or distance G₃) between power semiconductor device 15 and the second metal pin (metal pin 34 or metal pin 37) can be set appropriately. The reliability of electrical connection between conductive circuit pattern 10 and the first metal pin and the reliability of electrical connection between power semiconductor device 15 and the second metal pin can be improved. The reliability of power semiconductor apparatus 1f, 1g can be improved.

In power semiconductor apparatus 1f, 1g and the method of manufacturing the same in the present embodiment, the first hole (hole 22) and the second hole (hole 23 or hole 24) have a tapered shape becoming narrower toward first main surface 10a of conductive circuit pattern 10.

With this configuration, the first distance between conductive circuit pattern 10 and the first metal pin (metal pin 31) and the second distance between power semiconductor device 15 and the second metal pin (metal pin 34 or metal pin 37) can be set appropriately. The reliability of electrical connection between conductive circuit pattern 10 and the first metal pin and the reliability of electrical connection between power semiconductor device 15 and the second metal pin can be improved. The reliability of power semiconductor apparatus 1f , 1g can be improved.

When the first metal pin (metal pin 31) is inserted into the first hole (hole 22), the center axis in the first longitudinal direction of the first metal pin is aligned with the center axis in the second longitudinal direction of the first hole by the side surface of the first hole even if the center axis in the first longitudinal direction of the first metal pin is misaligned with the center axis in the second longitudinal direction of the first hole. The first conductive bonding member (conductive bonding member 32) is formed uniformly around the first metal pin. When the second metal pin (metal pin 34 or metal pin 37) is inserted into the second hole (hole 23 or hole 24), the center axis in the third longitudinal direction of the second metal pin is aligned with the center axis in the fourth longitudinal direction of the second hole by the side surface of the second hole even if the center axis in the third longitudinal direction of the second metal pin is misaligned with the center axis in the fourth longitudinal direction of the second hole. The second conductive bonding member (conductive bonding member 35 or conductive bonding member 38) is formed uniformly around the second metal pin. With this configuration, even when stress is applied to the first conductive post (conductive post 30) and the second conductive post (conductive post 33 or conductive post 36) due to change in ambient temperature, the stress can be prevented from being strongly applied locally to a part of the first conductive post (conductive post 30) and the second conductive post (conductive post 33 or conductive post 36). The reliability of the first conductive post (conductive post 30) and the second conductive post (conductive post 33 or conductive post 36) can be improved, and the reliability of power semiconductor apparatus 1f, 1g can be improved. The productivity of power semiconductor apparatus 1f, 1g can be improved.

In power semiconductor apparatus 1f, 1g and the method of manufacturing the same in the present embodiment, the first metal pin (metal pin 31) includes a first body (body 61) and a first head (head 62) provided at a third distal end of the first body with respect to first main surface 10a of conductive circuit pattern 10. The second metal pin (metal pin 34 or metal pin 37) includes a second body (body 64 or body 67) and a second head (head 65 or head 68) provided at a fourth distal end of the second body with respect to first main surface 10a of conductive circuit pattern 10. The first hole has a first small diameter portion (small diameter portion 71) accommodating the first body. The first hole has a first large diameter portion (large diameter portion 72) accommodating the first head. The second hole has a second small diameter portion (small diameter portion 74 or small diameter portion 77) accommodating the second body. The second hole has a second large diameter portion (large diameter portion 75 or large diameter portion 78) accommodating the second head.

With this configuration, the first distance between conductive circuit pattern 10 and the first metal pin (metal pin 31) and the second distance between power semiconductor device 15 and the second metal pin (metal pin 34 or metal pin 37) can be set appropriately. The reliability of electrical connection between conductive circuit pattern 10 and the first metal pin and the reliability of electrical connection between power semiconductor device 15 and the second metal pin can be improved. The reliability of power semiconductor apparatus 1f, 1g can be improved.

### Fifth Embodiment

In the present embodiment, any one of power semiconductor apparatuses 1, 1a, 1b, 1c, 1d, 1e, 1f, 1g in the foregoing first to fourth embodiments is applied to a power conversion apparatus. Although the present disclosure is not limited to any particular power conversion apparatus, the application of any one of power semiconductor apparatuses 1, 1a, 1b, 1c, 1d, 1e, 1f, 1g in the present disclosure to a three-phase inverter will be described below as a sixth embodiment.

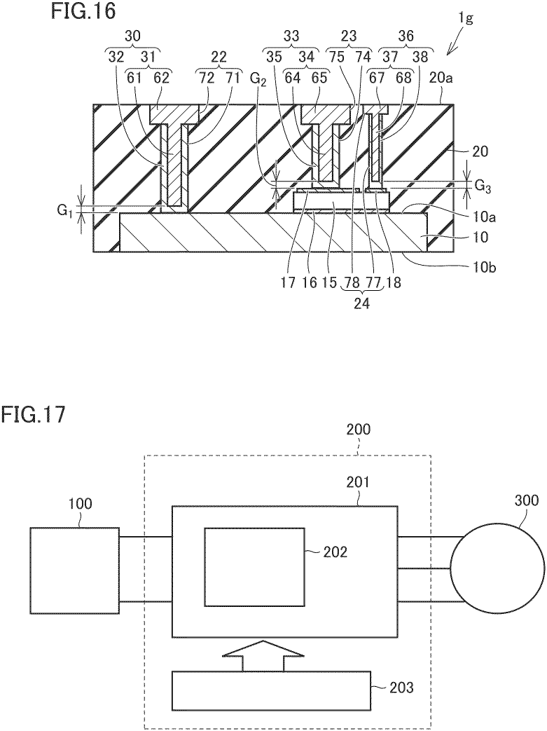

A power conversion system illustrated in FIG. 17 is configured with a power source 100, a power conversion apparatus 200, and a load 300. Power source 100 is a DC power source and supplies DC power to power conversion apparatus 200. Power source 100 may be composed of, for example, but not limited to, a DC system, a solar battery, or a storage battery or may be composed of a rectifier circuit or an AC/DC converter connected to an AC system. Power source 100 may be composed of a DC/DC converter that converts DC power output from a DC system into another DC power.

Power conversion apparatus 200 is a three-phase inverter connected between power source 100 and load 300 and converts DC power supplied from power source 100 into AC power and supplies AC power to load 300. As illustrated in FIG. 17, power conversion apparatus 200 includes a main conversion circuit 201 to convert DC power into AC power and output AC power, and a control circuit 203 to output a control signal for controlling main conversion circuit 201 to main conversion circuit 201.

Load 300 is a three-phase motor driven by AC power supplied from power conversion apparatus 200. Load 300 is not limited to any particular applications and is a motor installed in a variety of electrical instruments and used as, for example, a motor for hybrid vehicles, electric vehicles, railroad vehicles, elevators, or air conditioners.

The detail of power conversion apparatus 200 will be described below. Main conversion circuit 201 includes switching elements (not illustrated) and freewheeling diodes (not illustrated). The switching elements switch a voltage supplied from power source 100, whereby main conversion circuit 201 converts DC power supplied from power source 100 into AC power and supplies AC power to load 300. There are a variety of circuit configurations of main conversion circuit 201. Main conversion circuit 201 according to the present embodiment may be a two-level three-phase full bridge circuit and include six switching elements and six freewheeling diodes connected in antiparallel with the respective switching elements. At least one of the switching elements and the freewheeling diodes of main conversion circuit 201 is a switching element or a freewheeling diode of a power semiconductor apparatus 202 corresponding to any one of power semiconductor apparatuses 1, 1a, 1b, 1c, 1d, 1e, 1f, 1g in the foregoing first to fourth embodiments. Six switching elements are connected in series two by two to form upper and lower arms, and the upper and lower arms constitute each phase ((U phase, V phase, W phase) of a full bridge circuit. The respective output terminals of the upper and lower arms, that is, three output terminals of main conversion circuit 201 are connected to load 300.

Main conversion circuit 201 also includes a drive circuit (not illustrated) to drive each switching element. The drive circuit may be contained in power semiconductor apparatus 202 or may be provided outside of power semiconductor apparatus 202. The drive circuit generates a drive signal for driving a switching element in main conversion circuit 201 and supplies the drive signal to the control electrode of the switching element of main conversion circuit 201. Specifically, a drive signal to turn on a switching element and a drive signal to turn off a switching element are output to the control electrode of each switching element, in accordance with a control signal from control circuit 203. When the switching element is kept ON, the drive signal is a voltage signal (ON signal) equal to or higher than a threshold voltage of the switching element. When the switching element is kept OFF, the drive signal is a voltage signal (OFF signal) equal to or lower than a threshold voltage of the switching element.

Control circuit 203 controls the switching elements of main conversion circuit 201 such that power is supplied to load 300. Specifically, the time (ON time) in which each switching element of main conversion circuit 201 is to be turned ON is calculated based on power to be supplied to load 300. For example, main conversion circuit 201 can be controlled by PWM control that modulates the ON time of switching elements in accordance with the voltage to be output to load 300. A control command (control signal) is output to a drive circuit of main conversion circuit 201 such that an ON signal is output to a switching element to be turned ON and an OFF signal is output to a switching element to be turned OFF, at each point of time. The drive circuit outputs an ON signal or an OFF signal as a drive signal to the control electrode of each switching element, in accordance with the control signal.

In the power conversion apparatus in the present embodiment, any one of power semiconductor apparatuses 1, 1a, 1b, 1c, 1d, 1e, 1f, 1g in the first to fourth embodiments is applied as power semiconductor apparatus 202 that constitutes main conversion circuit 201. In power semiconductor apparatuses 1, 1a, 1b, 1c, 1d, 1e, 1f, 1g in the first to fourth embodiments, since the first conductive post (conductive post 30) and the second conductive post (conductive post 33 or conductive post 36) can be formed with a larger height, the distance between power semiconductor device 15 included in power semiconductor apparatus 1, 1a, 1b, 1c, 1d, 1e, 1f, 1g and control circuit 203 can be increased. The reliability of the power conversion apparatus can be improved.

In the present embodiment, the present disclosure is applied to a two-level three-phase inverter. However, the present disclosure is not limited thereto and can be applied to a variety of power conversion apparatuses. In the present embodiment, the present disclosure is applied to a two-level power conversion apparatus but may be applied to a three-level power conversion apparatus or a multi-level power conversion apparatus. When the power conversion apparatus supplies power to a single-phase load, the present disclosure may be applied to a single-phase inverter. When the power conversion apparatus supplies power to a DC load or the like, the present disclosure can be applied to a DC/DC converter or an AC/DC converter.

The power conversion apparatus to which the present disclosure is applied is not limited to a case where the load is a motor as described above, and may be used as a power supply device for an electric discharge machine or a laser machine, or an induction heating cooker or a wireless charging system, or may be used as a power conditioner for a solar power system or a power storage system.

The first to fifth embodiments and modifications thereof disclosed here should be understood as being illustrative rather than being limitative in all respects. At least two of the first to fifth embodiments and modifications thereof disclosed here may be combined unless a contradiction arises. The scope of the present disclosure is shown not in the foregoing description but in the claims, and it is intended that all modifications that come within the meaning and range of equivalence to the claims are embraced here.

### REFERENCE SIGNS LIST

1, 1a, 1b, 1c, 1d, 1e, 1f, 1g power semiconductor apparatus, 2, 2a power semiconductor module, 10 conductive circuit pattern, 10a first main surface, 10b main surface, 15 power semiconductor device, 16 back electrode, 17 first front electrode, 18 second front electrode, 20 sealing member, 20a second main surface, 22, 23, 24 hole, 30, 33, 36 conductive post, 31, 34, 37 metal pin, 32, 35, 38 conductive bonding member, 32p, 32q, 32r, 35p, 35q, 35r, 38p, 38q, 38r conductive bond precursor, 40 mold, 41 fixed part, 42 movable part, 43, 44, 45 mold pin, 50, 50a printed circuit board, 51 insulating substrate, 51a third main surface, 51b fourth main surface, 52 wiring, 53 first wiring portion, 54 second wiring portion, 55 third wiring portion, 61, 64, 67 body, 62, 65, 68 head, 63, 66, 69 leg, 71, 74, 77 small diameter portion, 72, 75, 78 large diameter portion, 100 power source, 200 power conversion apparatus, 201 main conversion circuit, 202 power semiconductor apparatus, 203 control circuit, 300 load.

1. A power semiconductor apparatus comprising:
a conductive circuit pattern including a first main surface;
a power semiconductor device bonded on the first main surface;
a sealing member sealing the first main surface and the power semiconductor device;
a first conductive post filling a first hole formed in the sealing member, and connected to the first main surface of the conductive circuit pattern; and
a second conductive post filling a second hole formed in the sealing member, and connected to the power semiconductor device, wherein
the first conductive post includes a first metal pin and a first conductive bonding member,
the second conductive post includes a second metal pin and a second conductive bonding member,
the first conductive bonding member fills between a first pin side surface of the first metal pin and a first side surface of the first hole and bonds the first metal pin to the conductive circuit pattern, and
the second conductive bonding member fills between a second pin side surface of the second metal pin and a second side surface of the second hole and bonds the second metal pin to the power semiconductor device.

2. The power semiconductor apparatus according to claim 1, wherein the first metal pin and the second metal pin are formed of copper, aluminum, gold, or silver.

3. The power semiconductor apparatus according to claim 1 , wherein the first conductive bonding member and the second conductive bonding member are formed of solder or metal fine particle sintered body.

4. The power semiconductor apparatus according to claim 1, wherein a first cross section of the first metal pin along a first longitudinal direction of the first metal pin and a second cross section of the second metal pin along a second longitudinal direction of the second metal pin have a T shape or an I shape.

5. The power semiconductor apparatus according to claim 1, wherein a first cross section of the first metal pin along a first longitudinal direction of the first metal pin and a second cross section of the second metal pin along a second longitudinal direction of the second metal pin have a tapered shape becoming narrower toward the first main surface or a serrated shape becoming narrower toward the first main surface.

6. The power semiconductor apparatus according to claim 1, wherein
a first diameter of a first proximal end of the first hole with respect to the first main surface is smaller than a second diameter of a first distal end of the first hole with respect to the first main surface, and the first hole positions the first metal pin in a direction normal to the first main surface, and
a third diameter of a second proximal end of the second hole with respect to the first main surface is smaller than a fourth diameter of a second distal end of the second hole with respect to the first main surface, and the second hole positions the second metal pin in the direction normal to the first main surface.

7. The power semiconductor apparatus according to claim 6, wherein the first hole and the second hole have a tapered shape becoming narrower toward the first main surface.

8. The power semiconductor apparatus according to claim 6, wherein
the first metal pin includes a first body and a first head provided at a third distal end of the first body with respect to the first main surface,
the second metal pin includes a second body and a second head provided at a fourth distal end of the second body with respect to the first main surface,
the first hole has a first small diameter portion accommodating the first body,
the first hole has a first large diameter portion accommodating the first head,
the second hole has a second small diameter portion accommodating the second body, and
the second hole has a second large diameter portion accommodating the second head.

9. The power semiconductor apparatus according to claim 1, wherein
the sealing member includes a second main surface away from the first main surface in a direction normal to the first main surface, and
a first end portion of the first conductive post and a second end portion of the second conductive post distal from the first main surface protrude from the second main surface.

10. The power semiconductor apparatus according to claim 1, wherein
the sealing member includes a second main surface away from the first main surface in a direction normal to the first main surface, and
a first end portion of the first conductive post and a second end portion of the second conductive post distal from the first main surface are flush with the second main surface.

11. A method of manufacturing a power semiconductor apparatus, the method comprising:
bonding a power semiconductor device on a first main surface of a conductive circuit pattern;
providing a sealing member sealing the first main surface and the power semiconductor device and having a first hole and a second hole;
forming a first conductive post in the first hole; and
forming a second conductive post in the second hole, wherein
providing the sealing member includes placing the conductive circuit pattern having the power semiconductor device bonded thereon in a cavity of a mold having a first mold pin and a second mold pin, injecting a sealing resin material into the cavity, and curing the sealing resin material to obtain the sealing member, the first mold pin being arranged corresponding to the first hole, the second mold pin being arranged corresponding to the second hole,
the first conductive post fills the first hole and is connected to the first main surface of the conductive circuit pattern,
the second conductive post fills the second hole and is connected to the power semiconductor device,
the first conductive post includes a first metal pin and a first conductive bonding member,
the second conductive post includes a second metal pin and a second conductive bonding member,
the first conductive bonding member fills between a first pin side surface of the first metal pin and a first side surface of the first hole and bonds the first metal pin to the conductive circuit pattern, and
the second conductive bonding member fills between a second pin side surface of the second metal pin and a second side surface of the second hole and bonds the second metal pin to the power semiconductor device.

12. The method of manufacturing a power semiconductor apparatus according to claim 11, wherein
forming the first conductive post in the first hole includes providing a first conductive bond precursor in paste or powder form in the first hole, bringing the first metal pin into contact with the first conductive bond precursor to arrange the first conductive bond precursor between the first metal pin and the conductive circuit pattern and between the first pin side surface of the first metal pin and the first side surface of the first hole, and heating and cooling the first conductive bond precursor to change the first conductive bond precursor into the first conductive bonding member, and
forming the second conductive post in the second hole includes providing a second conductive bond precursor in paste of powder form in the second hole, bringing the second metal pin into contact with the second conductive bond precursor to arrange the second conductive bond precursor between the second metal pin and the power semiconductor device and between the second pin side surface of the second metal pin and the second side surface of the second hole, and heating and cooling the second conductive bond precursor to change the second conductive bond precursor into the second conductive bonding member.

13. The method of manufacturing a power semiconductor apparatus according to claim 11, wherein
forming the first conductive post in the first hole includes providing a first conductive bond precursor in the first hole, heating, the first conductive bond precursor to melt the first conductive bond precursor, dipping the first metal pin in the molten first conductive bond precursor to arrange the molten fifirst conductive bond precursor between the first metal pin and the conductive circuit pattern and between the first pin side surface of the first metal pin and the first side surface of the first hole, and cooling the first conductive bond precursor to change the first conductive bond precursor into the first conductive bonding member, and
forming the second conductive post in the second hole includes providing a second conductive bond precursor in the second hole, heating the second conductive bond precursor to melt the second conductive bond precursor, dipping the second metal pin in the molten second conductive bond precursor to arrange the molten second conductive bond precursor between the second metal pin and the power semiconductor device and between the second pin side surface of the second metal pin and the second side surface of the second hole, and cooling the second conductive bond precursor to change the second conductive bond precursor into the second conductive bonding member.

14. The method of manufacturing a power semiconductor apparatus according to claim 11, wherein
forming the first conductive post in the first hole includes applying a first conductive bond precursor on the first metal pin, inserting the first metal pin having the first conductive bond precursor applied thereon into the first hole to arrange the first conductive bond precursor between the first metal pin and the conductive circuit pattern and between the first pin side surface of the first metal pin and the first side surface of the first hole, and heating and cooling the first conductive bond precursor to change the first conductive bond precursor into the first conductive bonding member, and
forming the second conductive post in the second hole includes applying a second conductive bond precursor on the second metal pin, inserting the second metal pin having the second conductive bond precursor applied thereon into the second hole to arrange the second conductive bond precursor between the second metal pin and the power semiconductor device and between the second pin side surface of the second metal pin and the second side surface of the second hole, and heating and cooling the second conductive bond precursor to change the second conductive bond precursor into the second conductive bonding member.

15. The method of manufacturing a power semiconductor apparatus according to claim 12, wherein
the first conductive bond precursor is heated using heat produced in the first metal pin, and
the second conductive bond precursor is heated using heat produced in the second metal pin.

16. The method of manufacturing a power semiconductor apparatus according to claim 11, wherein a first cross section of the first metal pin along a first longitudinal direction of the first metal pin and a second cross section of the second metal pin along a second longitudinal direction of the second metal pin have a T shape or an I shape.

17. The method of manufacturing a power semiconductor apparatus according to claim 11, wherein a first cross section of the first metal pin along a first longitudinal direction of the first metal pin and a second cross section of the second metal pin along a second longitudinal direction of the second metal pin have a tapered shape becoming narrower toward the first main surface or a serrated shape becoming narrower toward the first main surface.

18. The method of manufacturing a power semiconductor apparatus according to claim 11, wherein
a first diameter of a first end of the first hole proximal to the first main surface is smaller than a second diameter of a second end of the first hole distal from the first main surface, and the first hole positions the first metal pin in a direction normal to the first main surface, and
a third diameter of a third end of the second hole proximal to the first main surface is smaller than a fourth diameter of a fourth end of the second hole distal from the first main surface, and the second hole positions the second metal pin in the direction normal to the first main surface.

19. A power conversion apparatus comprising:
a main conversion circuit including the power semiconductor apparatus according to claim 1, the main conversion circuit converting input power and outputting the converted power; and
a control circuit to output a control signal for controlling the main conversion circuit to the main conversion circuit.
